(19) United States
(12) Patent Application Publication
(10) Pub. No.: US 2023/0078946 A1
(43) Pub. Date: Mar. 16, 2023

(54) Hybrid Development of EUV Resists

(71) Applicant: Tokyo Electron Limited, Tokyo (JP)

(72) Inventors: Steven Grzeskowiak, Albany, NY (US); Lior Huli, Delmar, NY (US); Angelique Raley, Albany, NY (US); Cong Que Dinh, Kumamoto (JP); Makoto Muramatsu, Kumamoto (JP); Seiji Nagahara, Tokyo (JP)

(21) Appl. No.: 17/943,729

(22) Filed: Sep. 13, 2022

Related U.S. Application Data
(60) Provisional application No. 63/244,309, filed on Sep. 15, 2021.

(51) Int. Cl. G03F 7/36; H01L 21/66; H01L 21/027; G03F 7/38; G03F 7/40; G03F 7/42

(52) U.S. Cl. CPC G03F 7/36; H01L 22/20; H01L 21/0274; G03F 7/38; G03F 7/40; G03F 7/422; G03F 7/2004

(57) ABSTRACT

A method of microfabrication includes depositing a photoresist film on a working surface of a semiconductor wafer, the photoresist film being sensitive to extreme ultraviolet radiation; exposing the photoresist film to a pattern of extreme ultraviolet radiation; performing a hybrid develop of the photoresist film. The hybrid develop includes executing a first development process to remove a first portion of the photoresist film; stopping the development of the photoresist film after the first development process, the photo resist film including a structure having a first critical dimension larger than a target critical dimension after the stopping; and after stopping the development, executing a second development process to remove a second portion of the photoresist film and shrinking the critical dimension of the structure from the first critical dimension to a second critical dimension that is less than the first critical dimension.

### CROSS-REFERENCE TO RELATED APPLICATIONS

This application claims the benefit of U.S. Provisional Application No. 63/244,309, filed on Sep. 15, 2021, which application is hereby incorporated herein by reference.

### TECHNICAL FIELD

The present invention relates generally to a system and method for developing extreme ultraviolet (EUV) photoresist patterns, and, in particular embodiments, to systems and methods for hybrid development of EUV photo resists.

### BACKGROUND

Semiconductor manufacturing includes several processing steps that involve forming patterns on the semiconductor substrates. These processing steps include, among others, coating the dielectric or conductive surface of the substrate with photo resist, developing a latent pattern, and transferring the pattern into the dielectric or conductive surface of the substrate by etching.

In microfabrication processes, a layer of photoresist is coated on a working surface (upper surface) of a substrate such as a semiconductor wafer. The photoresist is subsequently patterned via photolithography to define a mask pattern for transferring to an underlayer by etching using the patterned resist as an etch mask. Patterning of the photo resist generally involves steps of coating, exposure, and development. A working surface of the substrate is coated with a film of photo resist. The photo resist is exposed through a lithographic mask (and associated optics) using, for example, micro-lithography. Patterned exposure is followed by a development process during which the removal of soluble regions of the photo resist occurs using either a wet (solvent) or a dry (gaseous) development process. Soluble regions can be exposed or non-exposed regions depending on the tone of the photoresist and developer used.

Extreme ultraviolet (EUV) lithography is a photolithography technology that uses photons within the extreme ultraviolet radiation range (124 nm-10 nm). Typically, a wavelength of 13.5 nm is used. EUV photo resists are usually metal-containing resists.

### SUMMARY

In one embodiment, a method of microfabrication includes depositing a photoresist film on a working surface of a semiconductor wafer, the photoresist film being sensitive to extreme ultraviolet radiation; exposing the photoresist film to a pattern of extreme ultraviolet radiation; performing a hybrid develop of the photoresist film. The hybrid develop includes executing a first development process to remove a first portion of the photoresist film; stopping the development of the photoresist film after the first development process, the photo resist film including a structure having a first critical dimension larger than a target critical dimension after the stopping; and after stopping the development, executing a second development process to remove a second portion of the photoresist film and shrinking the critical dimension of the structure from the first critical dimension to a second critical dimension that is less than the first critical dimension.

In one embodiment, a method of microfabrication includes depositing a photoresist film on a working surface of a semiconductor wafers, the photoresist film being sensitive to extreme ultraviolet radiation; exposing the photoresist film to a pattern of extreme ultraviolet radiation to form an EUV photoresist pattern; executing a wet development process to remove a first portion of the EUV photoresist pattern resulting in structures having a first critical dimension larger than a target critical dimension; and after executing the wet development process, executing a dry development process to remove a second portion of the EUV photoresist pattern resulting in the structures having the target critical dimension.

In one embodiment, a semiconductor manufacturing apparatus includes a first development chamber and a second development chamber. The apparatus is configured to sequentially process a substrate in the first development chamber and the second development chamber.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a block diagram of a semiconductor apparatus for forming an EUV photoresist pattern in accordance with embodiments;

FIGS. 2A-2F are three-dimensional isometric projection views of process steps for forming an EUV photoresist pattern in accordance with embodiments;

FIGS. 3A-3F are plan views of process steps for forming an EUV photoresist pattern in accordance with embodiments;

FIG. 4 is a flow diagram describing the formation of an EUV photoresist pattern using hybrid develop in accordance with embodiments;

FIG. 5 is a flow diagram describing the formation of an EUV photoresist pattern using hybrid develop in accordance with embodiments; and

FIG. 6 is a flow diagram describing a method for reducing the dose of EUV radiation required to expose a pattern in EUV photoresist in accordance with embodiments.

### DETAILED DESCRIPTION OF ILLUSTRATIVE EMBODIMENTS

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

EUV radiation and EUV photoresists behave differently than conventionally used deep ultraviolet (DUV) radiation and DUV photo resists. Different techniques are therefore used with EUV lithography. EUV photoresists are typically metal-containing resists instead of DUV carbon containing photoresists and are less transparent to the exposing radiation. EUV resists are typically thinner (20 nm to 40 nm) than DUV resists (2000 nm to 4000 nm), are more difficult to expose completely through the photoresist layer, and are more difficult to develop, especially at critical dimensions less than 30 nm.

EUV photoresists can be wet photoresists (wet-deposited) or dry photoresists (dry-deposited. Wet photoresists are typically deposited by spin-on deposition, that is, a wafer is rotated rapidly, and a liquid resist is deposited on the spinning wafer which causes the photoresist to spread out and coat the surface of the wafer. Dry photoresists are deposited in gaseous or molecular form by any number of dry deposition techniques including chemical vapor deposition, atomic layer deposition, physical vapor deposition, sputter deposition and so forth.

EUV resists can be wet developed using solvents or can be dry developed using gases. Conventional EUV photoresist development processes use a single wet development (or a single dry development) process to resolve a latent image exposed in the EUV photoresist.

Wet development processes inherently suffer from capillary forces caused by the surface tension of liquids. These capillary forces can lead to pattern distortion, pattern collapse, and other defects especially at critical dimensions less than 30 nm.

Gas phase chemical etch development, referred to as dry development, does not suffer from such capillary forces. This provides certain patterning advantages in terms of reducing pattern collapse and increasing process windowing. Unfortunately, the dry development process suffers from scumming and residues that may remain after the dry develop process—especially in lower EUV dose regions such as near the bottom of the EUV photoresist layer. Attempts to fix this residue problem include using sputtering and other processes to try to mitigate the residue. The dry development can be performed with or without plasma assist.

Embodiments disclosed include multi-step, hybrid development processes for developing EUV photoresists. Hybrid development processes can include a wet development process followed by one or more dry development processes or can include a first less aggressive dry development process followed by a second more aggressive dry development process or processes. In general, a first mild development step is followed by a subsequent more aggressive development step. Intermediate heat treatments or a UV treatment can be used to strengthen photoresist structures and to alter development rates prior to subsequent development steps.

This multi-step, hybrid development method can be applied to wet deposited photoresists or dry deposited photoresists. For wet developed EUV photoresists embodiment hybrid development processes prevent pattern collapse. For dry developed EUV photoresists embodiment hybrid development processes mitigate scumming/residue. The result is enhanced lithographic performance of printed features in EUV photoresist patterns.

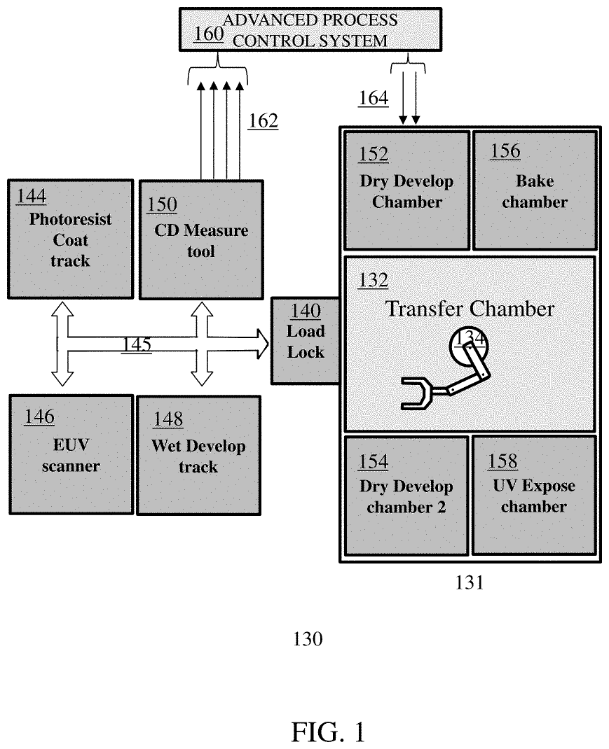

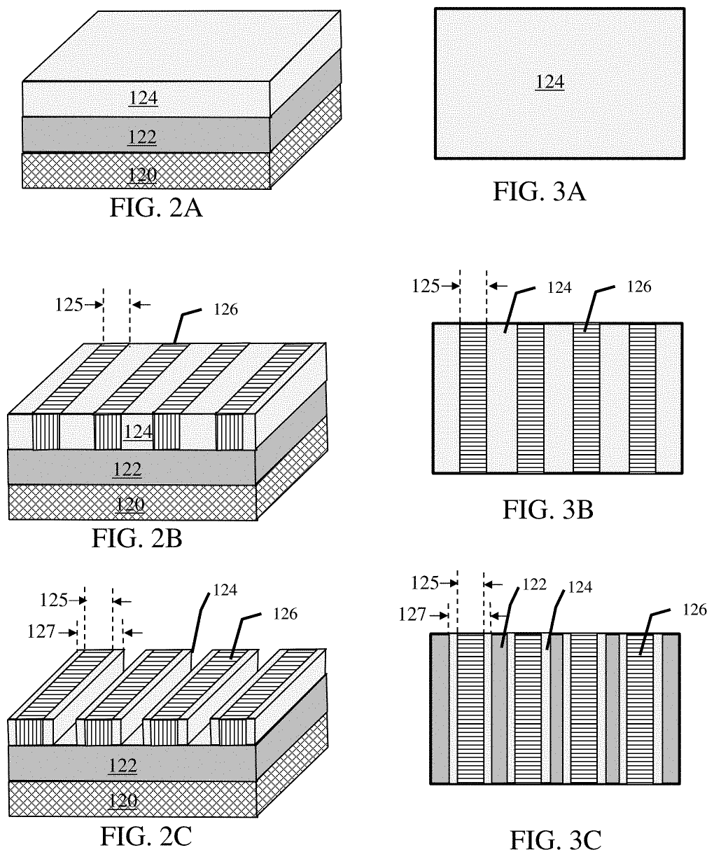

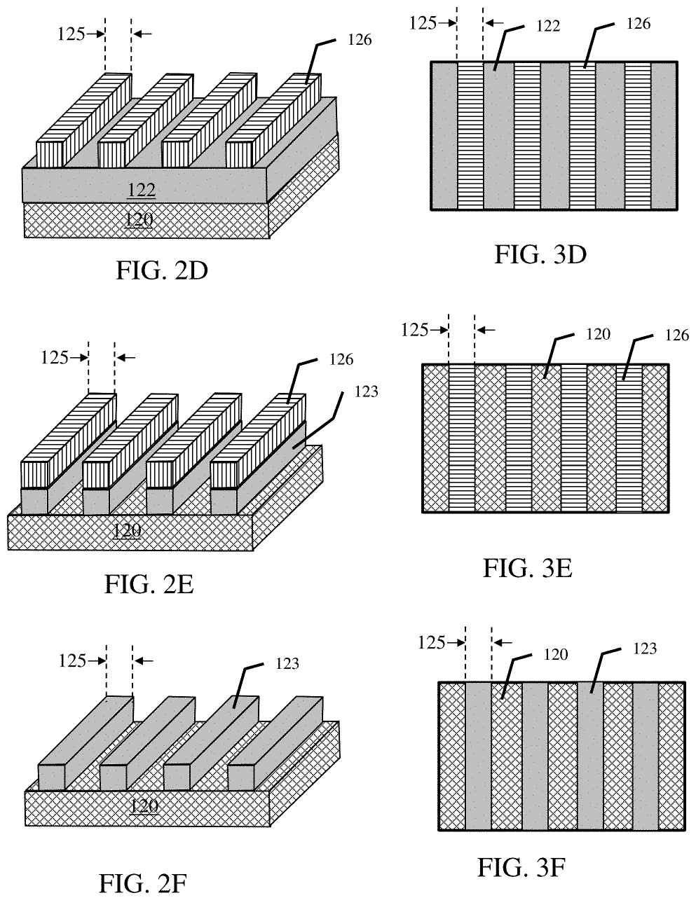

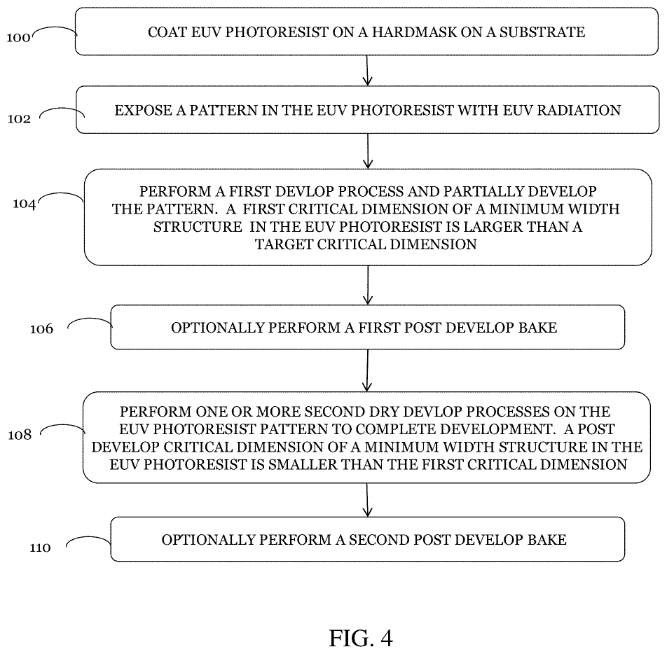

An apparatus for forming EUV patterns on semiconductor substrates according to embodiments will be described using FIG. 1. Accordingly, a process flow will be described using FIG. 4, along with FIGS. 2A-2F and 3A-3F.

FIG. 1 is a block diagram of a semiconductor apparatus for forming a pattern in EUV photoresist using hybrid development procedures in accordance with embodiments.

Embodiments of the present disclosure are enabled by the apparatus described herein that allows hybrid development within a common tool or tool platform.

The hybrid develop apparatus 130 includes a hybrid dry develop tool 131 capable of performing embodiment dry/dry hybrid development processes. The hybrid develop apparatus 130 also includes additional manufacturing tools such as a wet develop track 148 that enables wet/dry hybrid development processes.

The example hybrid dry develop tool 131 in FIG. 1 includes a load lock 140 for transferring substrates/wafers from outside the hybrid dry develop tool 131 to inside the transfer chamber 132. Attached to the transfer chamber 132 are a dry develop chamber 152 which can dry develop exposed EUV photoresist with less aggressive develop conditions and a second dry develop chamber 154 capable of developing the EUV photoresist pattern with more aggressive process conditions. Also included in the example hybrid dry develop tool 131 are an optional bake chamber 156 for optionally baking the substrate after developing, and an optional UV exposure chamber 158 for optionally blanket exposing the substrate with UV radiation prior to the dry develop process.

As illustrated in FIG. 1, in various embodiments, the hybrid dry develop apparatus 120 may additionally include a wet develop track 148 to enable embodiment hybrid wet/dry development procedures to be performed. The hybrid develop apparatus 130 may also include other processing tools associated with EUV processing such as a photoresist coat track 144 for depositing photoresist on substrates, an EUV scanner 146 for exposing the photoresist with EUV radiation through a lithography mask, and a critical dimension measurement tool 150 such as a scanning electron microscope (SEM) or transmission electron microscope (TEM). A wafer/substrate transport system 145 such as a robotic system can transfer the wafers/substrates between the various processing tools in the hybrid development apparatus 130 and transport them to and from the hybrid dry development tool 131.

Embodiment dry/dry hybrid development processes can be performed in the dry development tool 131. An embodiment hybrid dry/dry development process can be performed in one of the dry develop chambers 152 or 154 by first partially developing the EUV pattern with a less aggressive dry develop process, stopping development. changing process conditions, and then performing a second developing step in the same chamber with a second more aggressive developing process. Alternatively, the first less aggressive dry development process can be performed in dry develop chamber 152 and the second more aggressive dry development process performed in dry develop chamber 154. In one or more embodiments, the dry development tool 131 is configured to sequentially process a substrate in the dry develop chamber 152 followed by the dry develop chamber 154, e.g., without having to go through a load lock.

Embodiment wet/dry hybrid development procedures can be performed in hybrid development apparatus 130 by performing the wet development step on wet development track 148 and then transferring the substrate/wafer into the hybrid dry development tool 131. The dry development portion of the embodiment hybrid wet/dry development procedure can be performed in dry develop chamber 152 or 154. The dry development process can be a chemical vapor development process, or a plasma etch development process. If desired the CD can be measured in the CD measure tool 150 post wet develop and prior to dry development. In one or more embodiments, the hybrid development apparatus 130 is configured to sequentially process a substrate in the wet development track 148 followed by the dry develop chamber 152 or 154.

An advanced process control system 160 (APC) may be coupled to some or all of the chambers and manufacturing tools in the hybrid develop apparatus 130. The APC system 160 may comprise computers and servers which gather massive amounts of data 162 from the processing chambers and manufacturing tools, analyze the data, compare analyzed results to specifications, and send instructions 164 to microprocessors in processing chambers and manufacturing tools to adjust process recipes to produce structures with target specifications. For example, the critical dimension (CD) measurement tool 150 can measure the CD on a structure in an EUV photoresist pattern after the first development process and send the data 162 to the APC system 160. The APC system 160 can then calculate the difference between a target CD specification and the measured CD and send instructions 164 to a microprocessor in the dry development chamber 152 to adjust the dry development recipe to produce the structure with the target CD post the dry development process.

FIG. 4 is a flow diagram describing the formation of an EUV photoresist pattern using hybrid develop in accordance with embodiments FIGS. 2A-2F illustrate three-dimensional isometric projection views while FIGS. 3A-3F illustrate plan views of the EUV photoresist pattern during various stages of the hybrid develop procedure.

Referring to block 100 in FIG. 4, along with FIGS. 2A and 3A, EUV photoresist 124 is deposited on hard mask material 122 overlying a semiconductor substrate 120 in photoresist coat track 144 in FIG. 1.

The substrate 120 may include a layer to be etched and in various embodiments may comprise device regions formed therein. The substrate may be a semiconductor wafer such as a silicon or gallium arsenide wafer, may be a chromium layer or other layer on a lithographic reticle, or may be a layer such silicon dioxide, silicon nitride, titanium, titanium nitride, or copper overlying a base substrate structure

In general, “substrate” as used herein generically refers to an object being processed. The substrate may include any material portion of structure of a device, particularly a semiconductor or other electronics device, and may, for example, be a base substrate structure, such as a semiconductor wafer, a lithographic reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The hard mask material 122 may be a dielectric material such as silicon dioxide, silicon nitride, or aluminum oxide or may be a conductive material such as titanium nitride or tantalum nitride. The hard mask material 122 is chosen to have high etch selectivity to the wet develop and to dry develop chemicals and also to have high etch selectivity to the substrate 120 to be etched. The substrate may be a dielectric material such as silicon dioxide, silicon nitride, may be a semiconductor material such as undoped single crystal silicon, or may be a conductive material such as titanium, titanium nitride, aluminum, copper, or doped single crystal silicon.

The EUV photoresist 124 can be an organometallic EUV resist. Organometallic EUV resists 124 comprise metal oxide cores surrounded by organic alkyl groups covalently bonded to the metal oxide cores. The metal oxide core can be tin oxide, hafnium oxide, zinc oxide, and zirconium oxide for example. The metal atoms in the metal oxide cores absorb EUV radiation more strongly than the carbon and oxygen atoms in organic polymer resists. The metal atoms make the organometallic EUV resists more sensitive to EUV radiation.

In block 102 of FIG. 4, and as illustrated in FIGS. 2B and 3B, EUV radiation, transmitted through a lithography reticle, is used to expose a pattern in the EUV photoresist layer 124. The EUV exposure may be performed in the EUV scanner 146 illustrated in FIG. 1.

The EUV photoresist pattern comprises exposed areas 126 and unexposed areas 124. For purposes of illustration, a positive EUV photoresist is used where exposure to EUV radiation renders the EUV photoresist 124 insoluble so as to form exposed areas 126. To form a minimum width structure in the semiconductor substrate 120, the EUV photoresist 124 is exposed with the dose of EUV radiation required to expose a minimum width line with a target critical dimension 125.

After the pattern is formed in the EUV photoresist 124, a post exposure bake (PEB) may be performed in bake chamber 156 in FIG. 1. The PEB is typically a 1-to-3-minute bake in air or nitrogen at a temperature of 50° C. to 250° C. The post EUV exposure bake conditions are selected to promote a degree of crosslinking in the exposed EUV photo resist 126 to improve structural strength, improve contrast, and reduce line edge roughness (LER).

FIGS. 2C and 3C illustrate the semiconductor device during fabrication after a first develop process, wherein FIG. 2C illustrates a three-dimensional isometric projection view while FIG. 3C illustrates a plan view.

Referring to block 104 of FIG. 4, along with FIGS. 2C and 3C, a first development step in a hybrid development procedure is performed according to various embodiments. The hybrid development procedure comprises two or more development processes. The first development process is a less aggressive development process that removes a first portion of the unexposed EUV photoresist 124. The first development step creates structures such as lines with a critical dimension 127 larger than the target critical dimension 125. The subsequent more aggressive dry development process in the hybrid develop procedure further shrinks the lines laterally. There can be some height removal of the EUV photoresist, but primary removal is lateral because of the EUV exposure concentration across the lines.

The first development step can be executed by wet development, by dry chemical vapor development, or by dry plasma development. Dry development can be executed in a separate dry developing tool 131 or in a track module. Thus, a hybrid development apparatus 130 can include both a wet development track 148 and dry development chambers 152 and 154.

A wet development process uses a solvent in which the unexposed EUV photoresist 124 is soluble. The wet develop process can be performed on wet develop track 148 in FIG. 1.

Alternatively, the first development process may be a dry develop process with less aggressive development conditions that partially develops the EUV photoresist pattern leaving minimum width structures with CDs larger than a target critical dimension. The dry develop process may be performed in dry develop chamber 152 in FIG. 1.

The wet development solvent may comprise an organic solvent, water, an acid, or a base, which may also include combinations thereof. The wet development solvent may comprise an aromatic compound (e.g., xylenes, toluene), an ether (e.g., anisole, tetrahydrofuran), an ester (e.g., propylene glycol monomethyl ether acetate, or PGMEA), an alcohol (e.g., isopropanol, 4-methyl 3-propanol, ketones, 2-heptaone, water, n-butyl acetate, acetic acid, or methyl isobutyl carbinol (MIBC). Acetic acid concentrations in water or in PGMEA may range from 0% to 10% for most hybrid wet development applications.

The dry development process may be either a chemical vapor etch develop process or a plasma etch develop process. A chemical vapor etch develop process is typically performed in a chamber with a showerhead above the substrate that dispenses the vapor etching gases uniformly across the substrate. The chemical vapor etching chamber may also have a substrate chuck that rotates to additionally improve develop uniformity. A dry plasma etch development process is typically performed in a plasma etch chamber with a showerhead above the substrate to dispense the etching gases uniformly across the substrate. An RF generator coupled to an antenna within the dry plasma etch develop chamber strikes and sustains the plasma. The plasma developing chamber may also have a substrate chuck that rotates to additionally improve vapor etch development uniformity. The substrate chuck may be biased with a voltage to add a sputter etch component to the plasma etch development process.

Dry chemical vapor development chemistry may depend on the composition of the corresponding EUV photoresist. Example chemical vapor development chemistries may comprise a halide, hydrogen halide, hydrogen gas, halogen gas, organic halide, acyl halide, a carbonyl halide, or a thionyl halide, which includes mixtures thereof. More specific examples include hydrogen fluoride, hydrogen chloride, hydrogen bromide, or hydrogen iodide. In one example, the chemical vapor developing gas is hydrogen bromide.

Dry plasma etch development chemistry may depend on the composition of the corresponding resist. Example dry plasma etch development chemistries may include a halide such as hydrogen halide, an organic halide, acyl halide, a carbonyl halide, or a thionyl halide, hydrogen gas, nitrogen gas, or halogen gas, which may include a mixture of these gases. In example dry plasma etch develop processes, the etching gases may comprise hydrogen chloride, hydrogen bromide, argon, or helium. In one example plasma etch development process, the etching gases may comprise hydrogen bromide and argon.

By way of a non-limiting example, a first development step may be a wet development process using PGMEA, 5% acetic acid, a mixture of acetic acid and PGMEA, or MIBC, and the second development step may be a dry chemical vapor development step using HBr.

Referring to block 106 of FIG. 4, an optional first post develop bake (PDB) may be performed in bake chamber 126 in FIG. 1. The PDB may be a 1-to-3-minute bake in air or nitrogen at a temperature of 50° C. to 250° C. The PDB bake conditions may be selected to promote a degree of crosslinking in the exposed EUV photo resist pattern 126 to alter the develop rate, to improve structural strength, to improve contrast, and to reduce line edge roughness (LER).

Referring to block 108 of FIG. 4 along with FIGS. 2D and 3D, one or more second dry develop processes may be performed to complete development of the EUV photoresist pattern. The dry develop process or processes may be performed in either the second dry develop chamber 154, the first dry develop chamber 152, or both. The dry develop processes may remove additional unexposed EUV photoresist 124. The width of a minimum width structure in the EUV photoresist pattern after the second dry etch development is less than the width after the first development process. The width of a minimum width structure post second dry etch development may equal a critical dimension specification 125.

The vapor etch chemicals for the second development process may be the same or may be different than for the first vapor etch development. The process conditions for the second vapor etch development may be the same or different from the process conditions for the first vapor etch development. For example, in the second vapor etch development processes, the temperature may be different, the chemical concentrations and flow rates may be different, and the pressure may be different than in the first vapor etch development process.

In block 110 of FIG. 4, after the EUV photoresist pattern is completely developed, an optional second post develop bake or hard bake may be performed in bake chamber 156 in FIG. 1. Post develop bakes are typically performed to increase thermal and mechanical stability of the EUV photoresist pattern 166 to withstand harsh conditions of subsequent processing steps. Since the EUV photoresist pattern 166 is removed post hard mask etch, this hardbake may usually be omitted.

FIGS. 2E and 3E are a three-dimensional isometric projection view and a plan view of the semiconductor structure after the hard mask material 122 is etched using the EUV photoresist pattern as an etch mask. In various embodiments, the hard mask material 122 is etched using an anisotropic plasma etching process to transfer the photoresist pattern into the hard mask layer producing a hard mask pattern 123.

FIGS. 2F and 3F are a three-dimensional isometric projection view and a plan view of the hard mask pattern 123 after the EUV photoresist pattern is removed. In embodiments, the EUV photoresist patterns are removed by ashing in oxygen plasmas or in halide plasmas.

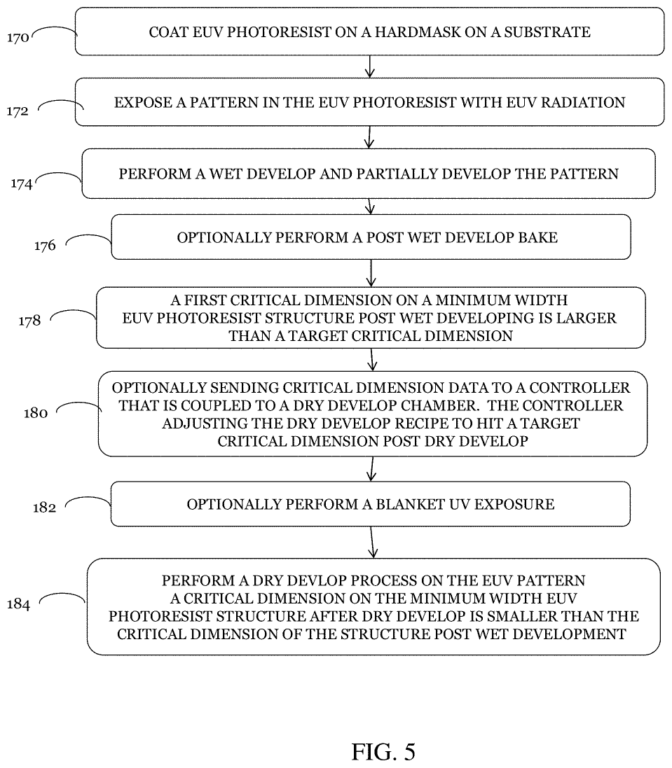

FIG. 5 is a flow diagram of blocks describing the major steps of embodiment wet/dry hybrid develop methods for forming a pattern in EUV photoresist. Hybrid development methods in this embodiment may use a first wet development process followed by a second dry development process. One advantage of these embodiments is that a critical dimension (CD) can be measured subsequent to the wet development and provide CD feedback correction to each wafer during dry development processing. CD measurements can be across wafer to monitor CD uniformity (CDU) or can be location specific. CD measurement can be inline on a track or performed in an offline CD measurement tool.

Critical dimension data can be sent to an APC system 160 coupled to the dry develop chamber 152 and to other modules and used to make adjustments to the dry develop process recipe and other process recipes to produce target critical dimensions and to improve across wafer uniformity. Modifications to heat treatments can be location specific (i.e., wafer zone temperature). Modified dry develop process conditions may include process variables such as wafer temperature, flow rate, time, dilution, or co-flow. CD monitoring may have environmental factors that vary day-to-day.

Methods herein can have two or more development steps and any number of bake steps. For example, bake steps can include a post exposure bake (PEB) before the first develop, a post first develop bake (PDB1), and a post second develop hard bake (PEB2). These baking steps are optional. These baking steps may be performed to improve structural stability, to alter the develop rates, to improve contrast, and to reduce line edge roughness.

As can be appreciated, there are many alternative embodiments contemplated herein. Development or developer can be dose sensitive. In one embodiment, the second developer may have a higher development rate compared to the first developer. The higher development rate may result from using different developer chemistries, or a same chemistry with different times/temperatures during treatment.

In some embodiments, an optional blanket UV exposure of the EUV photoresist pattern may replace the post first development bake (PDB1). The optional UV exposure can help with the second development by strengthening the exposed EUV photoresist and rendering it less susceptible to pattern collapse during second development. The UV exposure may be a flood exposure in various embodiments. In certain embodiments, the UV exposure may be location specific in that certain coordinate locations on the wafer receive more UV treatment compared to other coordinate locations on the wafer. The UV exposure may enable using a more aggressive developer for the second development step.

The three-dimensional isometric projection views of the EUV photoresist pattern in FIGS. 2A-2F and the plan views of the EUV photoresist pattern in FIGS. 3A-3F are used to illustrate the blocks in the FIG. 5 flow diagram.

FIGS. 2A and 3A illustrate block 170 in FIG. 5. DUV photoresist 124 is coated on hard mask material 122 overlying a semiconductor substrate 120 in photoresist coat module 114 in FIG. 1.

In block 172 of FIG. 5, illustrated in FIGS. 2B and 3B, an EUV scanner 146 projects EUV radiation through a lithographic reticle exposing a pattern in the EUV photoresist layer 124.

In block 174 of FIG. 5, illustrated in FIGS. 2C and 3C, a wet development step in a hybrid development procedure is performed according to embodiments. The wet development process may be performed on wet develop track 148 in FIG. 1. The wet development process may be a less aggressive development process that removes a first portion of the unexposed EUV photoresist 124. After wet development, minimum width structures in the EUV photoresist pattern can have a critical dimension 127 larger than a target critical dimension 125.

The wet development solvent may comprise an organic solvent, water, an acid, or a base. The wet development solvent may comprise an aromatic compound, an ether, an ester, an alcohol, a ketone, 2-heptaone, water, n-butyl acetate, propylene glycol methyl ether acetate (PGMEA), acetic acid, or methyl isobutyl carbinol (MIBC), which may include combinations thereof. In an example wet development process, the solvent is a 5% acetic acid solution. In another example wet development processes, the solvent is PGMEA or MIBC.

In block 176 of FIG. 5, an optional post wet develop bake (PDB) can be performed in bake chamber 156 in FIG. 1.

In block 178 of FIG. 5, a critical dimension of a minimum width structure in the partially developed EUV photoresist pattern can be measured in the CD measure tool 150 in FIG. 1. The critical dimension 127 measured post the wet development process is larger than a target critical dimension 125.

In block 180 of FIG. 5, post wet develop critical dimension data 162 is optionally sent to a controller such as the advanced process control (APC) system 160 illustrated in FIG. 1. The APC system 160 can compare the critical dimension data post wet develop to the target critical dimension specification. The APC system 160 can then send instructions 164 to a microprocessor in the dry develop chamber 152 to adjust the dry develop process recipe to produce structures with the target critical dimension post dry developing.

In block 182 of FIG. 5, the EUV photoresist pattern 126 may be optionally exposed with blanket UV radiation in UV expose chamber 158. The blanket UV radiation additionally exposes the exposed EUV photoresist 126 and the unexposed EUV photoresist 124. Typically, when the EUV photoresist pattern is blanket exposed with UV radiation a post wet develop bake is not done. The blanket UV radiation may have a uniform intensity across the substrate 120 or the intensity may vary across the substrate 120 to improve the post development uniformity. In various embodiments, the wavelength of UV radiation during the optional blanket exposure ranges from about 130 nm to 300 nm, for example between 150 nm and 200 nm in one embodiment. EUV photoresist 124 is transparent to the longer wavelength UV radiation. The UV radiation exposes the EUV photoresist 124 uniformly from the top surface to the bottom surface. The blanket UV radiation additionally cross links exposed EUV resist 126 increasing strength and rendering it more insoluble. The UV induced cross linking in previously unexposed EUV resist 124 is insufficient to significantly impact development. An advantage of this embodiment is that the blanket UV exposure reduces the dose of EUV radiation required for patterning EUV photoresist 124. This increases throughput through EUV scanners.

In block 184 of FIG. 5, illustrated in FIGS. 2D and 3D, one or more dry develop processes using an embodiment hybrid development procedure are performed to complete development of the EUV photoresist pattern. This dry develop process or processes can be performed in either dry develop chamber, 152 or 154. The dry develop process or processes remove additional unexposed EUV photoresist 124. A width of a structure in the EUV photoresist pattern after the dry etch development process or processes is less than the width of the same structure after the wet development process. The width of a minimum width structure post dry etch development may be equal a critical dimension specification 125. The APC controller of the APC system 160 can adjust the dry etch development recipe or recipes based upon feedback critical dimension data to ensure the structure width meets the critical dimension specification 125 post dry etch development.

The dry develop process can be a chemical vapor etch development process, a plasma etch development process, or may be a series of chemical vapor etch development and plasma etch development processes. In an example chemical vapor etch development process the vapor etch gas is hydrogen bromide. In an example plasma etch development process, the plasma development gases are hydrogen bromide and argon.

As mentioned previously, hybrid develop processes can reduce the dose of EUV radiation required to produce a target critical dimension (reduced EUV dose to size).

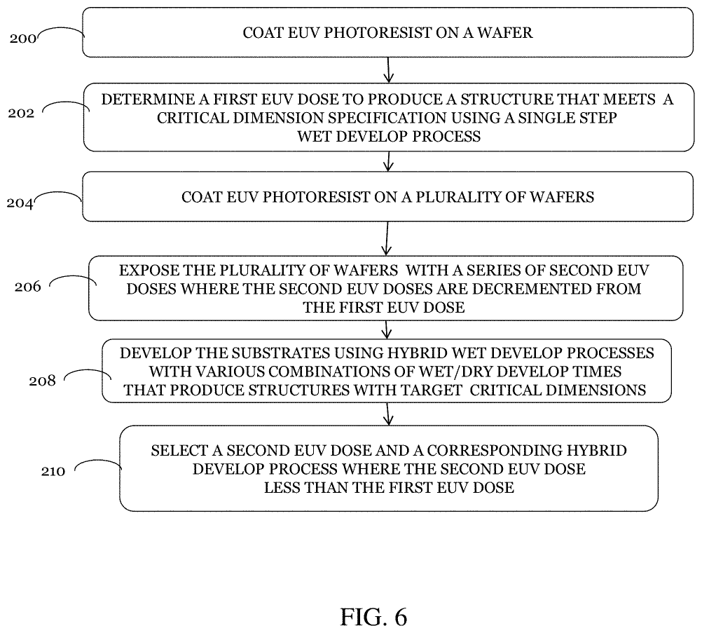

FIG. 6 is a flow diagram of blocks describing the major steps of a method for reducing the dose of EUV radiation required when using embodiment hybrid development processes. The hybrid development process may be wet/dry or dry/dry according to embodiments. A wet develop/dry chemical vapor develop hybrid process is used to illustrate these embodiments. An advantage of these embodiments is that throughput of wafers through EUV scanners can be increased, and cycle time reduced.

In block 200 of FIG. 6, illustrated in FIGS. 2A and 3A, a wafer is coated with EUV photoresist 124.

In block 202 of FIG. 6, a first dose of EUV radiation required to produce a target critical dimension is determined. The EUV pattern is developed using a one-step wet development process. In an example wet development process, the solvent is PGMEA with 5% acetic acid.

In block 204, a series of wafers are coated with EUV photoresist 124.

In block 206, the series of wafers are exposed through a lithographic mask in an EUV scanner with a series of doses of EUV radiation decremented from the first dose of EUV radiation.

In block 208, these wafers are developed using hybrid develop procedures comprising a wet develop process followed by a dry develop process. For each EUV exposure dose, a design of experiments (DOE) can be performed where the variables are the type of wet developer and wet developer time and the type of dry developer and dry developer time. The hybrid develop conditions can be chosen to produce structures that meet post develop critical dimension specifications. In one example, two wafers were exposed with equal doses of EUV radiation (73 mJ/cm²). A width on a structure is 18.5 nm when the pattern is developed using the standard wet development process (acetic acid). The width on the same structure is 14.5 nm when the pattern is developed using an embodiment hybrid wet/dry development process consisting of the standard wet development process with reduced time followed by chemical vapor development using a hydrogen bromide. The 18.5 nm target can be produced with the embodiment hybrid development process using a lower dose of EUV radiation.

In block 210 of FIG. 6, a second EUV dose along with a corresponding hybrid develop process is selected. The second EUV dose, is chosen to be an EUV dose (lower than the first EUV dose), that still produces an EUV pattern with target CDs and with an adequate manufacturing window. In one example, the second EUV dose is more than 15% lower than the first EUV dose. In another example, the second EUV dose is approximately 20% lower than the first EUV dose. The lower second EUV dose reduces cycle time through bottleneck EUV scanners. This enables significant cost savings by reducing the number of EUV steppers required.

Of course, the order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

As can be appreciated there are many combinations of multi-step hybrid EUV photo resist development methods contemplated herein. In one embodiment, EUV-sensitive photoresist is coated on a wafer, then exposed, then a post exposure bake is executed followed by a first development process followed by an optional post develop bake followed by a second development process with an optional final hard bake. In another embodiment, EUV-sensitive photoresist is coated on a wafer, then exposed, then a post exposure bake is executed followed by a first development process followed by an optional blanket UV exposure followed by a second development process with an optional final hard bake.

By using hybrid, multi-step development processes herein with multiple development steps and/or bake steps, lithographic performance is improved. This can include wet or dry development and combinations thereof. Using a first wet development step prior to the second (or subsequent) dry development step removes resist in the lower dose regions where a majority of residue is formed but does not fully resolve the critical features. This avoids pattern distortion or collapse and prevents other defects. At the same time, dose to size required to print the desired features can be reduced through process modifications at each step. The subsequent dry development process step mitigates pattern collapse through lack of capillary forces while further resolving critical features. The dry develop process can be repeated until a desired (target) critical dimension (CD) is achieved. The hybrid, multi-step development method disclosed herein provides a pathway to lessen pattern collapse probability and to lessen scumming/residues while at the same time providing CD stability control.

In the preceding description specific details have been set forth, such as a particular geometry of a processing system and description of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. Various additional operations may be performed and/or described operations may be omitted in additional embodiments.

Example embodiments of the invention are summarized here. Other embodiments can also be understood from the entirety of the specification as well as the claims filed herein.

Example 1. A method of microfabrication includes depositing a photoresist film on a working surface of a semiconductor wafer, the photoresist film being sensitive to extreme ultraviolet radiation; exposing the photoresist film to a pattern of extreme ultraviolet radiation; performing a hybrid develop of the photoresist film. The hybrid develop includes executing a first development process to remove a first portion of the photoresist film; stopping the development of the photoresist film after the first development process, the photo resist film including a structure having a first critical dimension larger than a target critical dimension after the stopping; and after stopping the development, executing a second development process to remove a second portion of the photoresist film and shrinking the critical dimension of the structure from the first critical dimension to a second critical dimension that is less than the first critical dimension.

Example 2. The method of example 1, where the second development process further includes: executing a dry development process to remove an incremental amount of the photoresist until the critical dimension of the structure is reduced to the target critical dimension.

Example 3. The method of one of examples 1 or 2, where the first development process is a wet development process using a developer solvent including propylene glycol monomethyl ether acetate, acetic acid, methyl isobutyl carbinol, 2-heptanone, or n-butyl acetate.

Example 4. The method of one of examples 1 to 3, where the developer solvent includes propylene glycol monomethyl ether acetate and acetic acid.

Example 5. The method of one of examples 1 to 4, further including measuring a critical dimension value of the structure subsequent to the first development process and in response to identifying a measured critical dimension value that is greater than a predetermined range, executing a corrective treatment process during the second development process.

Example 6. The method of one of examples 1 to 5, further including performing a first thermal treatment after the exposing the photoresist to a pattern of EUV and performing a second thermal treatment after the first development process and prior to the second development process.

Example 7. The method of one of examples 1 to 6, where a bake time and a bake temperature of the first thermal treatment differs from a bake time and a bake temperature of the second thermal treatment.

Example 8. The method of one of examples 1 to 7, where the second development process includes chemical vapor etch development using a gas including hydrogen chloride, hydrogen bromide, argon, or helium.

Example 9. The method of one of examples 1 to 6, 8, where the second development process includes a plasma etch development process using a gas including hydrogen chloride, hydrogen bromide, argon, or helium.

Example 10. The method of example 1, where the first development process is a first dry development process with a first photoresist dry development rate; the second development process is a second dry development processes with a second dry development rate; and where the first dry development rate is less than the second dry development rate.

Example 11. The method of example 1, where the first development process is a wet development process, and the second development process is one or more dry development processes.

Example 12. The method of one of examples 1 to 11, further including: determining a first dose of EUV radiation for producing a target critical dimension using a single develop process; and determining a second dose of EUV radiation for producing the target critical dimension using the hybrid develop, the second dose being less than the first dose; and where exposing the photoresist resist includes exposing the photoresist resist with the second dose.

Example 13. A method of microfabrication includes depositing a photoresist film on a working surface of a semiconductor wafers, the photoresist film being sensitive to extreme ultraviolet radiation; exposing the photoresist film to a pattern of extreme ultraviolet radiation to form an EUV photoresist pattern; executing a wet development process to remove a first portion of the EUV photoresist pattern resulting in structures having a first critical dimension larger than a target critical dimension; and after executing the wet development process, executing a dry development process to remove a second portion of the EUV photoresist pattern resulting in the structures having the target critical dimension.

Example 14. The method of example 13, further including: measuring a critical dimension subsequent to the wet development process and prior to the dry development process; and in response to identifying measured critical dimension values that are greater than a predetermined range, executing a corrective treatment process that brings the critical dimension values within the predetermined range.

Example 15. The method of one of examples 13 or 14, further including performing a first bake after exposing the photoresist film to patterned EUV radiation and performing a second bake after the wet development process and prior to the dry development processes.

Example 16. The method of one of examples 13 to 15, further including exposing the EUV photoresist pattern with UV light after the wet development process and prior to the dry development process.

Example 17. The method of one of examples 13 to 16, where a solvent for the wet development process includes 2-heptanone, n-butyl acetate, propylene glycol methyl ether acetate, or methyl isobutyl carbinol.

Example 18. The method of one of examples 13 to 17, where the dry develop process includes chemical vapor etching with hydrogen bromide.

Example 19. The method of one of examples 13 to 16, 18, where the dry develop process includes plasma etching with a gas including hydrogen chloride, hydrogen bromide, argon, or helium.

Example 20. A semiconductor manufacturing apparatus including: a first development chamber; and a second development chamber, the apparatus being configured to sequentially process a substrate in the first development chamber and the second development chamber.

Example 21. The apparatus of example 20, where the first development chamber is a wet development chamber for treating the substrate with a liquid-phase development chemistry, and the second development chamber is a dry development chamber for treating a substrate with a gas-phase development chemistry.

Example 22. The apparatus of one of examples 20 or 21, further including: a plasma etching chamber configured for anisotropic etching of semiconductor wafers; and where a gas-phase development chemistry in the dry development chamber removes photoresist material after exposure to a pattern of EUV radiation.

Example 23. The apparatus of one of examples 20 to 22, further including: the first development chamber is a first dry development chamber for treating a substrate with a first gas-phase development chemistry; and the second development chamber is a second development chamber for treating a substrate with a second gas-phase development chemistry, a development rate of the first gas-phase development chemistry is less than a development rate of the second gas-phase development chemistry.

Example 24. The apparatus of one of examples 20 to 23, where the gas-phase development chemistry is a chemical vapor etch chemistry.

Example 25. The apparatus of one of examples 20 to 24, where the gas-phase development chemistry is a plasma enhanced vapor etch chemistry.

Example 26. A method of microfabrication, the method including: depositing a photoresist film on a working surface of semiconductor wafers, the photoresist film being sensitive to extreme ultraviolet radiation; determining a first dose of extreme ultraviolet radiation for fully developing the photoresist film with a wet development process using a first set of the semiconductor wafers; exposing a second set of the semiconductor wafers with the photoresist film to a second dose of extreme ultraviolet radiation, the second dose being less than the first dose; and developing the photoresist film on each of the second set of semiconductor wafers using a corresponding hybrid develop process including a wet develop process followed by a dry develop process.

Example 27. The method of example 26, further including determining the second dose of EUV radiation, where the determining the second dose of EUV radiation and the corresponding hybrid develop process further includes: depositing the photoresist film over the working surface of a plurality of semiconductor wafers; exposing the plurality of semiconductor wafers with a series of doses of EUV radiation decrementing from the first dose; performing a series of hybrid developments on the plurality of semiconductor wafers using a series of wet develop times and a series of dry develop times, where the hybrid developments achieves a target critical dimension; and selecting the second dose of EUV radiation and a corresponding hybrid develop process for developing a further wafer, where the second dose of EUV radiation is lower than the first dose.

Example 28. The method of one of examples 26 or 27, where the second dose of EUV radiation is 15% or more lower than the first dose.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of microfabrication, the method comprising:
depositing a photoresist film on a working surface of a semiconductor wafer, the photoresist film being sensitive to extreme ultraviolet radiation;
exposing the photoresist film to a pattern of extreme ultraviolet radiation;
performing a hybrid develop of the photoresist film, the hybrid develop comprising:
executing a first development process to remove a first portion of the photoresist film;
stopping the development of the photoresist film after the first development process, the photo resist film comprising a structure having a first critical dimension larger than a target critical dimension after the stopping; and
after stopping the development, executing a second development process to remove a second portion of the photoresist film and shrinking the critical dimension of the structure from the first critical dimension to a second critical dimension that is less than the first critical dimension.

2. The method of claim 1, wherein the second development process further comprises:
executing a dry development process to remove an incremental amount of the photoresist until the critical dimension of the structure is reduced to the target critical dimension.

3. The method of claim 1, wherein the first development process is a wet development process using a developer solvent comprising propylene glycol monomethyl ether acetate, acetic acid, methyl isobutyl carbinol, 2-heptanone, or n-butyl acetate.

4. The method of claim 3, wherein the developer solvent comprises propylene glycol monomethyl ether acetate and acetic acid.

5. The method of claim 1, further comprising measuring a critical dimension value of the structure subsequent to the first development process and in response to identifying a measured critical dimension value that is greater than a predetermined range, executing a corrective treatment process during the second development process.

6. The method of claim 1, further comprising performing a first thermal treatment after the exposing the photoresist to a pattern of EUV and performing a second thermal treatment after the first development process and prior to the second development process.

7. The method of claim 6, wherein a bake time and a bake temperature of the first thermal treatment differs from a bake time and a bake temperature of the second thermal treatment.

8. The method of claim 1, wherein the second development process comprises chemical vapor etch development using a gas comprising hydrogen chloride, hydrogen bromide, argon, or helium.

9. The method of claim 1, wherein the second development process comprises a plasma etch development process using a gas comprising hydrogen chloride, hydrogen bromide, argon, or helium.

10. The method of claim 1, wherein the first development process is a first dry development process with a first photoresist dry development rate; the second development process is a second dry development processes with a second dry development rate; and wherein the first dry development rate is less than the second dry development rate.

11. The method of claim 1, wherein the first development process is a wet development process, and the second development process is one or more dry development processes.

12. The method of claim 1, further comprising:
determining a first dose of EUV radiation for producing a target critical dimension using a single develop process; and
determining a second dose of EUV radiation for producing the target critical dimension using the hybrid develop, the second dose being less than the first dose; and
wherein exposing the photoresist resist comprises exposing the photoresist resist with the second dose.

13. A method of microfabrication, the method comprising:
depositing a photoresist film on a working surface of a semiconductor wafers, the photoresist film being sensitive to extreme ultraviolet radiation;
exposing the photoresist film to a pattern of extreme ultraviolet radiation to form an EUV photoresist pattern;
executing a wet development process to remove a first portion of the EUV photoresist pattern resulting in structures having a first critical dimension larger than a target critical dimension; and
after executing the wet development process, executing a dry development process to remove a second portion of the EUV photoresist pattern resulting in the structures having the target critical dimension.

14. The method of claim 13, further comprising:
measuring a critical dimension subsequent to the wet development process and prior to the dry development process; and
in response to identifying measured critical dimension values that are greater than a predetermined range, executing a corrective treatment process that brings the critical dimension values within the predetermined range.

15. The method of claim 13, further comprising performing a first bake after exposing the photoresist film to patterned EUV radiation and performing a second bake after the wet development process and prior to the dry development processes.

16. The method of claim 13, further comprising exposing the EUV photoresist pattern with UV light after the wet development process and prior to the dry development process.

17. The method of claim 13, wherein a solvent for the wet development process comprises 2-heptanone, n-butyl acetate, propylene glycol methyl ether acetate, or methyl isobutyl carbinol.

18. The method of claim 13, wherein the dry develop process comprises chemical vapor etching with hydrogen bromide.

19. The method of claim 13, wherein the dry develop process comprises plasma etching with a gas comprising hydrogen chloride, hydrogen bromide, argon, or helium.

20. A semiconductor manufacturing apparatus comprising:
a first development chamber; and
a second development chamber, the apparatus being configured to sequentially process a substrate in the first development chamber and the second development chamber.
